(19) United States
(12) Patent Application Publication
(10) Pub. No.: US 2002/0164830 A1
(43) Pub. Date: Nov. 7, 2002

(54) Method for inline monitoring of a device's pattern profile

(76) Inventors: Hsin Yi Chang, Keelung (TW); Yun Hsiu Chen, Hsinchu (TW); Lung Hui Tsai, Hsinchu (TW)

Correspondence Address: BIRCH STEWART KOLASCH & BIRCH, PO BOX 747, FALLS CHURCH, VA, 22040-0747, US

(21) Appl. No.: 09/945,790

(22) Filed: Sep. 5, 2001

(30) Foreign Application Priority Data
May 1, 2001 (TW) 90110403

(51) Int. Cl. H01L 21/66; G01R 31/26

(52) U.S. Cl. 438/14; 438/15

(57) ABSTRACT

A method for inline monitoring of a device's pattern profile is disclosed. An insulator is deposited on the patterned layer to be detected by high density plasma chemical vapor deposition. A defect measurement device or refraction measurement device is used to compare the difference of the insulator in nearby dies in corresponding local areas. The insulator deposited on the patterned layer reflects the abnormal pattern profile (such as under cut, footing, or taper) and the normal pattern profile of the patterned layer. Thus, the abnormal pattern profile can be detected and qualified by defect measurement or refraction measurement devices.

### BACKGROUND OF THE INVENTION

1. Field of the Invention

The present invention relates in general to a method for inline monitoring of a device's pattern profile. In particular, the present invention relates to a method for inline monitoring and quantifying of a layer's abnormal pattern profile.

2. Description of the Related Art

In deep sub-micron processes, with the gradual shrinking of line width, it is difficult to control the pattern profile of the device. When performing ADI (after develop inspection) and AEI (after etching inspection), it is impossible to explicitly measure abnormal profiles, such as undercut, footing or taper, using a defect measurement device (such as KLA). If the abnormal pattern profile cannot be detected inline, the abnormal processes cannot be modified at the necessary stage.

### SUMMARY OF THE INVENTION

The object of the present invention is to provide a method for measuring abnormal pattern profiles.

To achieve the above-mentioned object, the present invention provides a method for inline monitoring of a device's pattern profile as follows. An insulator is deposited by high density plasma chemical vapor deposition on the patterned layer to be detected. A defect measurement device or refraction measurement device compares differences in insulators in nearby dies in corresponding local areas.

A defect measurement device compares the reflection difference of insulators in nearby dies in corresponding local areas, and locates the die wherein the abnormal pattern profile is situated. This die is then marked as defective. The refraction measurement device compares the refraction difference of the insulator in nearby dies in corresponding local areas.

The insulator deposited on the patterned layer reflects the abnormal pattern profile (such as under cut, footing, or taper) and the normal pattern profile of the patterned layer. Thus, the abnormal pattern profile can be detected and qualified by the defect measurement device or refraction measurement device.

The present invention provides a method for inline monitoring of a device's pattern profile in different dies, comprising the following steps. An insulator, such as a silicon oxide layer, is deposited on the patterned layer by high density plasma chemical vapor deposition, and the thickness of the insulator is ½ to 1.5 times the height of the patterned layer. The maximal height difference of the insulator in nearby dies in corresponding local areas is monitored by defect measurement device or refraction measurement device.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 is a cross-section of normal pattern and abnormal pattern profiles in a layer.

FIGS. 2A-2B are cross-sections illustrating the method of monitoring the pattern profile of a layer according to the embodiment of the present invention.

### DETAILED DESCRIPTION OF THE PREFERRED EMBODIMENT

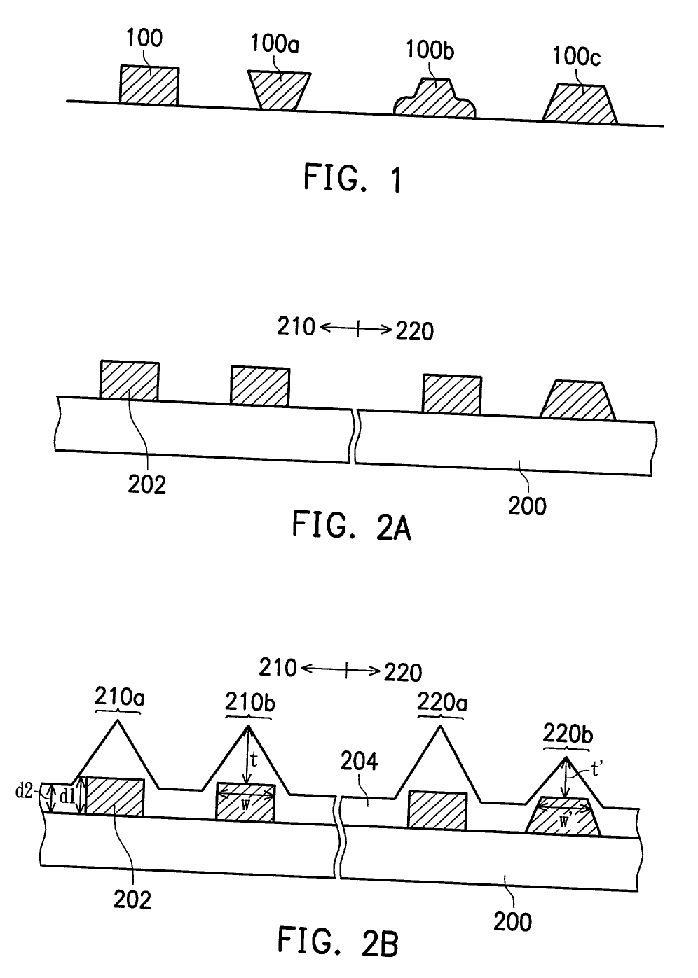

The pattern profile of the layer formed after developing and etching affects the electrical properties and yield of the device. The normal pattern profile 100 is shown in FIG. 1. Since abnormal pattern profiles, such as undercut 100a, footing 100b, or taper 100c, may occur. Thus, AEI is needed to inspect the etching process. The present invention provides a method for monitoring and quantifying possible abnormal pattern profiles by depositing an insulator with good gap filling ability on the patterned layer to be detected. The insulator is deposited by high density plasma chemical vapor deposition (HDPCVD). Because the height of the insulator reflects the original pattern it profile in each area, a die with abnormal pattern profile on the layer can be detected by defect measurement device or reflection measurement device. To clearly illustrate the present invention, a detailed embodiment accompanying FIGS. 2A and 2B is described as follows.

Referring to FIG. 2A, a patterned layer 202 is formed on a wafer 200, which comprises several dies, such as 210 and 220 as indicated. The height of the patterned layer 202 is d₁. The patterned layer 202 can be any layer of the interconnections.

Turning to FIG. 2B, an insulator 204 with good gap filling ability, which reflects the pattern profile of the patterned layer 202, is deposited on the patterned layer 202. The maximal height t of the insulator 204 on the top of the patterned layer 202 is related to the width w of the patterned layer 202 in the corresponding area as follows:

t∝a×w

Where “a” is the coefficient of the height d₁, pattern profile and density of the patterned layer 202. If the patterned layer 202 has different widths w in different areas, the local maximal heights t of the insulator 204 in the corresponding area are different. The insulator 204 can be a silicon oxide layer, and can be formed by preferred HDPCVD. The deposition thickness (d₂) must be within a range such that it is able to reflect the pattern profile of the patterned layer 202. The preferred height of the insulator 204 is about ½ to 1.5 times the height (d₁) of the patterned layer 202. In the figures, the height (d₁) of the patterned layer 202 is about 4000 Å, and the thickness (d₂) of the insulator 204 is about 3000 Å.

The local maximal heights of the insulator 204 between the die 210 and the die 220 in the same corresponding area are compared, and the differences in the corresponding local maximal heights in different dies show in reflection and refraction. Thus, the defect measurement device is used to compare the nearby dies in the corresponding area. If the pattern profile is abnormal, the local insulator 204 has an abnormal height. The insulator 204 with different heights has different reflection and refraction, which can be detected by the defect measurement device. Thus, the pattern profile of the patterned layer 204 can be monitored inline.

For example, the defect measurement device is used to compare the local area 210a of the die 210 and the corresponding local area 220a of the die 220. The pattern profiles in area 210a and area 220a are normal, so the maximal heights of the insulator 204 in these two areas are equal to “t”. Hence, no difference of reflections or refractions shows in the defect measurement device. The local area 210b of the die 210 and the corresponding local area 220b of the die 220 are then compared. The pattern profile of the patterned layer 202 in local area 220b is taper having top width w′ not w, that is, abnormal, so the local maximal height of the local insulator 204 is t′ not t. In such situation, the reflection and refraction in the local area 220a and that in the local area 220b are different and can be detected by a defect measurement device.

According to the above-mentioned method, the pattern profile of the patterned layer 202 can be monitored inline to find the abnormal pattern profile in the right moment. Then the engineers can execute the following analysis to get the deviation of the process condition. Thus, the abnormal process can be modified in time.

Summing up the embodiment, the invention provides benefits as follows:

(1) The present invention can find the abnormal pattern profile by depositing an insulator, which has good gap filling ability and can reflect the local pattern profile, and comparing the local maximal height of the insulator in different dies with the defect measure mechine.

(2) The abnormal pattern profile can be fined by a defect or reflection measurement device. Thus, the abnormality can be quantified.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method for inline monitoring of a device's pattern profile, comprising:
forming a patterned layer on a wafer, wherein the wafer comprises several dies;
depositing an insulator on the patterned layer; and
comparing the difference of the insulator in nearby dies in corresponding local areas.

2. The method as claimed in claim 1, wherein the insulator is a silicon oxide layer.

3. The method as claimed in claim 1, further comprising the following steps:
depositing the insulator by high density plasma chemical vapor deposition.

4. The method as claimed in claim 1, wherein the thickness of the insulator is ½ to 1.5 times the height of the patterned layer.

5. A method for inline monitoring of a device's pattern profile, comprising:
forming a patterned layer on a wafer, wherein the wafer comprises several dies;
depositing an insulator on the patterned layer by high density plasma chemical vapor deposition; and
comparing the height difference of the insulator in nearby dies in corresponding local areas.

6. The method as claimed in claim 5, wherein the insulator is a silicon oxide layer.

7. The method as claimed in claim 5, wherein the thickness of the insulator is ½ to 1.5 times the height of the patterned layer.

8. The method as claimed in claim 5, wherein the comparing step is conducted based on the difference of reflection and refraction.

9. The method as claimed in claim 5, wherein the comparing step is conducted by a defect measurement device.

10. The method as claimed in claim 5, wherein the comparing step is conducted by a refraction measurement device.
